(19) United States
(12) Patent Application Publication
(10) Pub. No.: US 2009/0246463 A1
(43) Pub. Date: Oct. 1, 2009

(54) ELECTRODE FOR DISCHARGE SURFACE TREATMENT, DISCHARGE SURFACE TREATMENT METHOD, FILM, AND FILM FORMING METHOD

(75) Inventors: Masao Akiyoshi, Tokyo (JP); Akihiro Goto, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: MITSUBISHI ELECTRIC CORPORATION, Chiyoda-ku, Tokyo (JP)

(21) Appl. No.: 12/088,632

(22) PCT Filed: Sep. 29, 2006
(86) PCT No.: PCT/JP2006/319404

§ 371 Date: Mar. 28, 2008

(30) Foreign Application Priority Data
Sep. 30, 2005 (JP) PCT/JP2005/018111

(51) Int. Cl. B32B 15/00; C23C 14/34; C22C 18/00

(52) U.S. Cl. 428/141; 204/298.13; 204/298.03; 204/192.15; 204/192.12; 420/524; 428/220

(57) ABSTRACT

An electrode that is used for discharge surface treatment in which, with a compact molded from metal powders or a compact obtained by heating the molded compact as an electrode, pulsed electric discharge is generated between the electrode and a workpiece to form a film of an electrode material, or a film of substance that reacts with the electrode material on a surface of the workpiece by discharge energy. The electrode contains 90 weight percent or more of one of Zn powders, Sn powders, and Ni powders. By using such an electrode for discharge surface treatment, a Zn, Sn, or Ni film less likely to separate from the surface of the workpiece can be formed, and the film can be a phosphide or sulfide reaction film in lubricant containing phosphorus or sulfur.

### TECHNICAL FIELD

The present invention relates to discharge surface treatment in which, with a compact molded from metal powders or metal compound powders, or a powdery compact obtained by heating the compact of the powders as an electrode, pulsed electric discharge is generated between the electrode and a workpiece in working fluid or in air to form a film of an electrode material, or a film of substance that the electrode material reacts with by discharge energy on a surface of the workpiece.

### BACKGROUND ART

From a view of durability and energy saving, it is necessary not to abrade surfaces of two metal components where the two components slide to each other. Generally, to suppress abrasion of a sliding portion in a boundary lubrication area between metal components, a reaction film is formed on the sliding portion.

The reaction film is a solid lubricating film that is made of iron sulfide, iron phosphate, or iron chloride that are not easily sheared and generated by chemical reaction of active element, such as phosphorus or chlorine contained in lubricant, due to friction heating. Such a reaction film can suppress abrasion.

Examples of materials that can form such a reaction film include Fe (iron), Sn (tin), Zn (zinc), Cr (chrome), and Ni (nickel).

Recently, discharge surface treatment has been developed as a method of forming a film that does not flake off easily.

In some conventional examples, a film is made from ceramics by using an electrode containing Zn or Cr, so that the film has sufficient hardness although the formation of a Zn film or a Cr film is not a main purpose of the examples.

For example, Japanese Patent Application Laid-Open No. H07-70761 discloses a technology for forming a surface layer on an Al surface or an Al alloy surface as base material. The surface layer is made of mixture of carbide made from reaction of dissolved carbon with an easily carbonizable metal contained in an electrode, and material of the electrode by performing surface treatment in working fluid for generating the dissolved carbon by discharge of petroleum or kerosene by using an electrode for discharge surface treatment. The electrode for discharge surface treatment is formed by compression molding in a predetermined shape by adding Al powders as binder metal to powders made of single metal that is easily carbonized, or mixed powders of more than two materials.

In other words, an object of the conventional technology disclosed in the Japanese Patent Application Laid-Open No. H07-70761 is to form a film made of carbide with sufficient hardness by carbonizing an easily carbonizable metal due to discharge, by using flexible Al powders as binder for molding easily carbonized metal powders.

If ratio of flexible material, such as Al, increases in a film, strength of the film largely decreases. Therefore, in the technology for forming a film with sufficient hardness disclosed in the Japanese Patent Application Laid-Open No. H07-70761, amount of Al powders contained in the electrode is suppressed as much as possible, resulting in limiting its weight ratio to 64 wt %.

As a material that serves similarly to Al powders, Zn powders can be used.

Furthermore, International Publication WO2004/108990 discloses a technology for forming a thick metal film by using an electrode made of mixture of Co (cobalt) of more than 40% by volume, which does not form carbide, with Cr₃C₂ (chrome carbide).

As examples of materials that do not form carbide, Ni, Fe, Al, Cu, or Zn in addition to Co are disclosed.
Patent document 1: Japanese Patent Application Laid-Open No. H07-70761
Patent document 2: International Publication WO2004/108990

### DISCLOSURE OF INVENTION

### Problem to be Solved by the Invention

Generally, in such a use environment where coefficient of friction or wear volume is controlled by using a reaction film, the reaction film of Zn or Cr phosphide or sulfide needs to be formed on a sliding portion. Such a reaction film has been formed by adding Zn or Zn compound as additive agent to lubricant. However, if large amount of Zn is added to the lubricant, the lubricant cannot work as the lubricant. Accordingly, there is limitation to the additive amount. On the other hand, if the additive amount is insufficient, the whole surface of the sliding surface cannot be coated by the film, resulting in failing to control coefficient of friction or to suppress wear volume.

In other words, if a Cr or Zn film can be formed on the sliding portion, such a film reacts with P (phosphorus) or S (sulfur) in lubricant, so that substantially the entire surface of the sliding portion can be coated by a reaction film. As a result, coefficient of friction can be controlled and abrasion of materials can be suppressed.

However, a conventional film formed by Zn or Cr plating flakes off easily with application of small load, so that such a film is not practical, and it is difficult to apply a Zn film or a Cr film for forming a reaction film on the sliding portion.

According to the Japanese Patent Application

Laid-Open No. H07-70761, an example in which Zn powders are mixed to an electrode for discharge surface treatment is disclosed as a film having sufficient hardness and made of carbonized metal that is easily carbonized. However, because the Zn powders are mixed as binder, their ratio to components is small. Therefore, it is difficult to form a reaction film due to affection of material of main component.

The International Publication WO2004/108990 discloses a technology for mixing Co powders at 40% by volume to Cr₃C₂ for forming a thick film. Furthermore, it is disclosed that Zn has the same effect as that of Co. However, disclosed fact is that Zn is mixed to Cr₃C₂, so that it is still difficult to form a reaction film with less amount of Zn or to control hardness of the surface of a component.

The present invention has been achieved to solve the above problems in the conventional technology and it is an object of the present invention to form a Zn, Sn, Cr, or Ni film, which can be a phosphide or sulfide reaction film in lubricant containing phosphorus or sulfur.

It is another object of the present invention to form a film having different hardness on the sliding portion, and particularly to provide a film with high abrasion resistance and various coefficients of friction, and does not separate even from the sliding portion in the boundary lubrication area, and to provide a method of forming such a film.

### Means for Solving Problem

According to the present invention, an electrode used for discharge surface treatment is a compact molded from metal powders or a compact obtained by heating the compact molded from metal powders. Between the electrode and a workpiece, pulsed electric discharge is generated to form a film of an electrode material, or a film of substance that reacts with the electrode material on a surface of the workpiece by discharge energy. The electrode contains 90 weight percent or more of one of Zn powders, Sn powders, and Ni powders.

### EFFECT OF THE INVENTION

According to an aspect of the present invention, it is possible to form a Zn, Sn, Cr, or Ni film, which hardly flake off, and the film can be a phosphide or sulfide reaction film in lubricant containing phosphorus or sulfur.

### BRIEF DESCRIPTION OF DRAWINGS

FIG. 1 is a diagram for explaining a process of forming an electrode for discharge surface treatment according to an embodiment of the present invention.

FIG. 2 is a graph of relation between molding pressure for forming an electrode by using Zn powders having an average particle diameter of 2 micrometers, and resistance of the electrode measured by the four-probe method specified in Japanese Industrial Standards JIS K 7194.

FIG. 3 is a graph of relation between a variation in resistance of an electrode molded from Zn powders having an average particle diameter of 2 micrometers and the amount of Zn on a surface of a film upon performing discharge surface treatment obtained by EDS (Energy-Dispersive X-ray Spectroscopy).

FIG. 4 illustrates film surfaces analyzed by TOF-SIMS after performing a sliding test.

FIG. 5 is a cross-sectional photograph and a graph of a result of line analysis of a Zn film formed on an SCM (chrome molybdenum steel) by using an electrode with a resistance of 0.02Ω under the conditions of a peak current of 5 A and a discharge time of 0.5 microsecond.

FIG. 6 is a graph for explaining relation between a product of discharge current and discharge time, and film-surface hardness upon forming a film on a workpiece made of S45C (carbon steel) having a hardness of around 300 HV by using an electrode with a resistance of 0.02Ω.

FIG. 7 is a graph of film hardness upon forming a film by using electrodes formed of TiC and Zn powders having a particle diameter of 2 micrometers mixed in different ratios.

### BEST MODE(S) FOR CARRYING OUT THE INVENTION

### First Embodiment

The principle of discharge surface treatment is described below.

A molded component made of metal or alloyed powder, or a heat-treated component generated by heating the molded component is used as an electrode. Such an electrode is placed in a work tank filled with petroleum working fluid with a predetermined interval kept from a base material (workpiece) set in the work tank. The electrode is used as cathode while the workpiece is used as anode, which are arranged not to come into contact with each other by using a servo mechanism on a main shaft, so that discharge is generated between the electrode and the workpiece. Although petroleum working fluid is described above, discharge can be generated in air or in water.

The workpiece and the electrode are molten or evaporated due to heat generated by discharge. A portion of molten electrode (molten particle) is delivered to a surface of the workpiece by blast or electrostatic force generated by vaporization.

When the portion of the molten electrode reaches the surface of the workpiece, the portion is re-solidified as a coating (film) thereon. The coating is deposited on the molten surface of the workpiece, and the workpiece and the coating are bonded together by diffusion bonding. Therefore, the coating hardly separates from the workpiece.

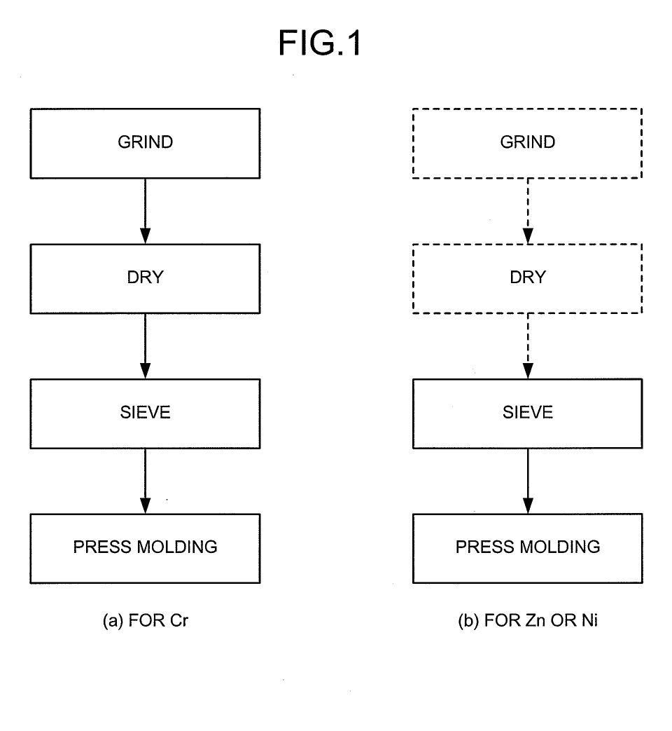

A process for forming an electrode for discharge surface treatment according to an embodiment of the present invention is described with reference to FIG. 1.

There are materials that react with phosphorus or sulfur contained in lubricant to form a reaction film. The materials include Zn, Sn, Cr, Ni, and the like, with which an electrode for forming the coating is fabricated.

According to the embodiment, Zn or Sn powders having an average particle diameter of 15 micrometers or less, or Cr or Ni powders having an average particle diameter of 4 micrometers or less are exclusively used.

When Cr powder is used, Cr powder having an average particle diameter of several tens of micrometers in the market place is grinded to have an average particle diameter of 4 micrometers or less by a grinder such as a ball mill.

After powders are grinded in fluid, it is necessary to evaporate the fluid and dry the powders. Electrode powders dried in such a manner are in a large clump.

To separate the large clump into pieces, the clump is sieved by using a sieve having a mesh size in a range from 100 micrometers to 300 micrometers.

When Zn, Sn, or Ni powders are used, it is possible to use particles having an average particle diameter of several tens of micrometers in the market place without grinding the powders. In this case, however, it is necessary to sieve the powders because the powders may be in a clump.

The mesh size of the sieve is determined based on press formability in a subsequent process and a size of powders, with which the powders can be separated into pieces by explosive force by the discharge when the powders are dropped in a space between the electrode and the workpiece during discharge coating process.

The average particle diameter of Zn or Sn powders to be used are larger than those of other metals because the Zn or Sn powders can be molten with less energy due to the fact that melting point of the Zn or Sn powders is about 400° C., while melting point of the other metals is about 1300° C.

When Zn, Sn, or other metal powders are treated in the same discharge condition, a film can be formed by using powders with a larger average particle diameter if the Zn or Sn powders are used. The Zn or Sn powders are preferable in that formability of an electrode increases as the particle diameter of powders increases.

However, if the average particle diameter of the Zn or Sn powders is larger than 15 micrometers, state of discharge becomes unstable, e.g., short circuit occurs between electrodes. Therefore, the average particle diameter of the Zn or Sn powders is preferable to be equal to or smaller than 15 micrometers.

The powders that have been sieved are placed in a mold, and pressed by a punch with a predetermined pressure, so that the powders are molded into a powder compact.

The Zn, Sn, or Ni powders have thin oxide films, which can be easily broken by applying pressure, so that powders can be metallically bonded to one another. On the other hand, formability of the Cr powders is not sufficient because oxide film of the Cr powders cannot be easily broken. By mixing wax, such as paraffin, with weight ratio in a range from 1% to 10% to the Cr powders, pressure by a press can be delivered more preferably, and formability can be improved.

A compact formed by compression molding can be used as an electrode for discharge surface treatment as long as the compact has a predetermined hardness by compression. If the hardness is not sufficient, the compact is heated to increase its hardness.

When wax is used, a compact is heated to a temperature higher than a melting point of the wax to remove the wax, so that an electrode for the discharge surface treatment is formed.

When an electrode is formed by using Zn, Sn, or Ni powders, the powders can be metallically bonded with one another by pressure by a press, so that an electrode having sufficient hardness can be formed without heating. However, when an electrode is formed by using Cr powders, the hardness of the electrode is not sufficient by pressure by a press, so that it is necessary to perform a heating process to heat the electrode to a temperature in a range from 300° C. to 500° C. after pressing.

### Example

A preferable example according to the first embodiment is described below.

In the example, Zn powders having an average particle diameter of 2 micrometers were purchased from the market place, and sieved by using a sieve having a mesh size of 300 micrometers, so that clumped powders in a size equal to or less than 300 micrometers were acquired, and an electrode was formed by compressing such powders.

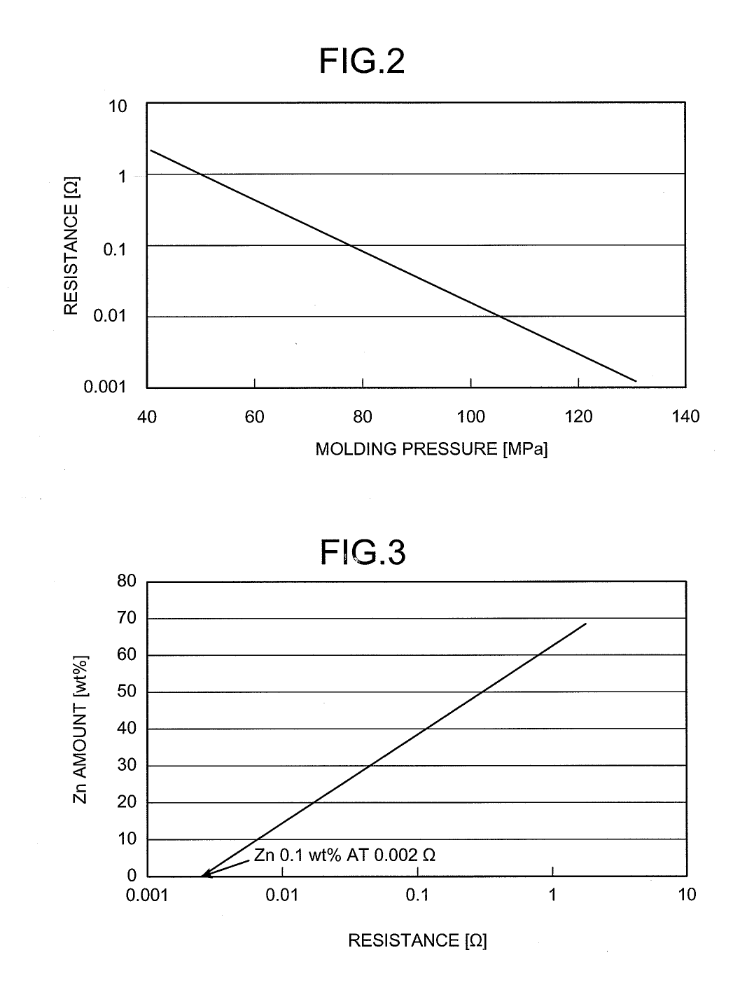

A relation between molding pressure for forming an electrode by using Zn powders having an average particle diameter of 2 micrometers, and resistance of the electrode measured by the four-probe method specified in Japanese Industrial Standards JIS K 7194 is shown in FIG. 2. According to the four-probe method, four needle probes are linearly arranged on an electrode, and a predetermined current is supplied between laterally placed two probes to acquire resistance by measuring electrical potential difference between medially placed two probes.

It can be seen from FIG. 2 that resistance of the electrode decreases as molding pressure increases.

When molding pressure to powders is not sufficient, less powders in the electrode are metallically bonded, so that resistance of the electrode increases. On the other hand, as the molding pressure increases, more powders are metallically bonded, so that the resistance decreases exponentially.

A condition of resistance of the electrode for forming a film is described below.

For maintaining a space between an end of the electrode and a workpiece, control is performed between the electrode and the workpiece in such a manner that voltage is applied between the electrode and the workpiece, and servo control is performed to stabilize the voltage to be detected between the electrodes. However, when resistance is so large (e.g., equal to or larger than 4Ω) that the electrode decreases the voltage between electrodes as caused by the space, a main shaft controls the end of the electrode so that the electrode comes closer to the workpiece to a distance corresponding to inter-electrode voltage. As a result, the electrode and the workpiece may come contact with each other.

If the electrode and the workpiece come contact with each other, it is difficult to apply voltage between the electrode and the workpiece, so that discharge is hardly generated.

In other words, if the resistance of the electrode is equal to or larger than 4Ω, it is difficult to perform servo control between the electrode and the workpiece, so that discharge is hardly generated.

FIG. 3 depicts relation between a variation in resistance of an electrode molded from Zn powders having an average particle diameter of 2 micrometers and the amount of Zn on a surface of a film upon performing discharge surface treatment obtained by EDS (Energy-Dispersive X-ray Spectroscopy).

The workpiece was made of carbon steel (S45C). The condition for forming a film was such that discharge current was 8 A, discharge time was 8 microseconds, area to be treated was 2×16, and treatment time was 2 minutes.

Zn amount was measured in an observation area in a size determined to be 200 times as large as a surface to be coated, and by using acceleration voltage of 15 kV.

Detection by analysis using the EDS was performed not only for a top surface of the film but for a predetermined depth (a few micrometers) from the surface.

Therefore, Fe, which is a component of the workpiece made of S45C under the film made of Zn on the surface, was detected more than Zn.

When the amount of Zn, which constitutes the film, increased, the amount of Fe decreased. This indicates that a thickness of Zn film has increased or a portion where Zn is accumulated has increased.

As shown in FIG. 3, the amount of Zn in the film with an electrode having a resistance of 0.002Ω was 0.1 wt %, and the amount of Zn increased as the resistance increased.

An electrode having resistance smaller than 0.002Ω means that the electrode has higher hardness. Accordingly, Zn as a film was less likely to separate from the electrode, so that the amount of Zn to be supplied from the electrode to the workpiece largely decreased, resulting in little accumulation of Zn or removal process.

As a result, resistance of the electrode needs to be equal to or larger than 0.002Ω for forming a Zn film.

A reaction film is effective with a thickness at atomic level, so that a film containing 0.1 wt % Zn coating a top surface of the workpiece can prevent abrasion. However, the reaction film arranged on a sliding surface is abraded in some cases, so that long-term durability of the thin Zn film decreases.

As disclosed in the International Publication WO2004/108990, content amount of Zn in a film formed by using a mixed electrode containing ceramics may be about 0.1 wt %. However, it is difficult to form a reaction film because materials other than Zn are present on the sliding surface. As a result, a counter workpiece is abraded.

As described above, for discharge surface treatment by using an electrode molded from Zn powders, it is possible to form an Zn film that serves as a reaction film on the surface of the workpiece by forming the electrode with resistance between 0.002Ω and 4Ω.

When a sliding portion of which surface is coated by a Zn, Cr, or Ni film is slid in a lubricant, the film reacts with phosphorus or sulfur contained in the lubricant, so that it is possible to form a phosphide or sulfide reaction film.

A sliding test was performed to a Zn film formed on a SCM 420 having around 1000 Vickers hardness (HV) by using an electrode having a resistance of 0.02Ω and a peak current of 7 A for discharge time of 0.5 microseconds, in a condition that lubricant containing S in a range from 0.06 wt % to 0.30 wt % and P in a range from 100 ppm to 600 ppm were dropped at 5 cc/min. The counter workpiece is a quenched/tempered steel pin made of SKS-95, of which end portion had curvature radius of 18 millimeters, and hardness was in a range from HRC 60 to HRC 64.

The end portion of the pin was pressed to the film with a load of 5 kgf, and slid back and forth for 50 millimeters with a cycle of 200 cpm. As a result, it was found that the reaction film was formed, coefficient of friction increased about 10% compared with a polished surface made of SCM 420, and wear volume decreased compared with unprocessed material.

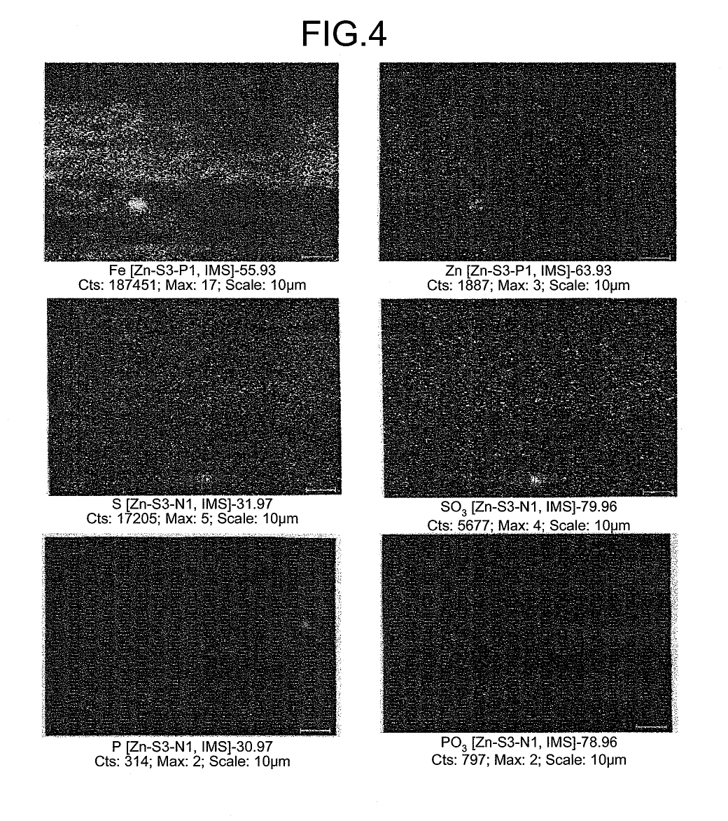

The surface with the film after performing the sliding test was analyzed by TOF-SIMS. A result of the TOF-SIMS analysis is shown in FIG. 4.

The TOF-SIMS analysis is an analysis method in which Ga⁺ ion is applied on the surface of a sample to emit secondary ion present in an element on the surface of the sample, so that the element is identified based on emission time due to mass of the secondary ion, and ion number is measured. In this analysis method, luminescent point of luminance corresponding to the ion number is generated on an image mapped in accordance with the surface of the sample, so that amount of the element is identified based on height of the luminance and the amount of the ion number.

As shown in FIG. 4, Zn, P, S, and SO₃ were distributed on the sliding surface, and it was found that ZnS and ZnSO₃ were present. The film and the counter workpiece were little abraded, realizing improvement in abrasion resistance of the reaction film made of zinc phosphate, ZnS, and ZnSO₃.

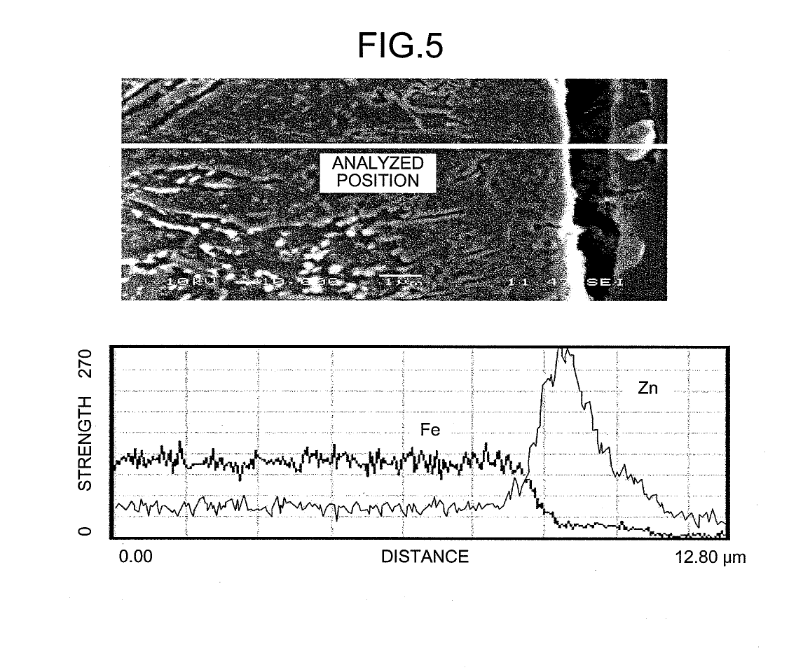

A cross-sectional photograph and a result of line analysis of a Zn film formed on an SCM by using an electrode with a resistance of 0.02Ω and a peak current of 5 A for discharge time of 0.5 microseconds is shown in FIG. 5.

A mixed layer of Fe and Zn was formed in which Fe was a main component of the workpiece and its amount decreased toward the film, while amount of Zn decreased toward the workpiece. It was found that the film formed in such a manner hardly separated from the workpiece.

The thickness of the film was about 2 micrometers including a diffusion layer.

The hardness of the surface of the workpiece affected the coefficient of friction and depth of wear of the sliding surface under boundary lubrication.

Generally, as the hardness of the surface decreases, the coefficient of friction decreases.

If the difference between the hardness of the abrasion target material and the hardness of the counter workpiece is large, either one of which hardness is smaller than that of the other one is abraded.

The film formed by discharge surface treatment can realize various hardness of the surface by changing a process condition. Thus, the discharge surface treatment is preferable for forming a film.

The hardness of solid metal of Zn or Ni capable of forming a reaction film is equal to or less than 100 HV, so that if the film made of Zn or Ni with thickness of 0.1 millimeter or more is deposited, the hardness of the surface of the film has the hardness as the same as or slightly larger than that of the solid metal of Zn or Ni.

For preventing abrasion, as described above, the hardness of the surface of the material needs to be equal to or larger than 200 HV because the hardness of steel, which is widely used as a counter workpiece, is equal to or larger than 200 HV.

A technology for increasing the hardness of the surface of the film for preventing abrasion is described below.

For example, if the thickness of the film is made thicker, the hardness of the surface of the film becomes the same as that of the metal forming a coating material as described above. However, if the thickness of the film is equal to or less than 10 micrometers, the hardness does not become the same as that of the metal forming the film, and varies due to process condition during formation of the film. Examples for adjusting the hardness of the surface of the film by changing the process condition during formation of the film are described below.

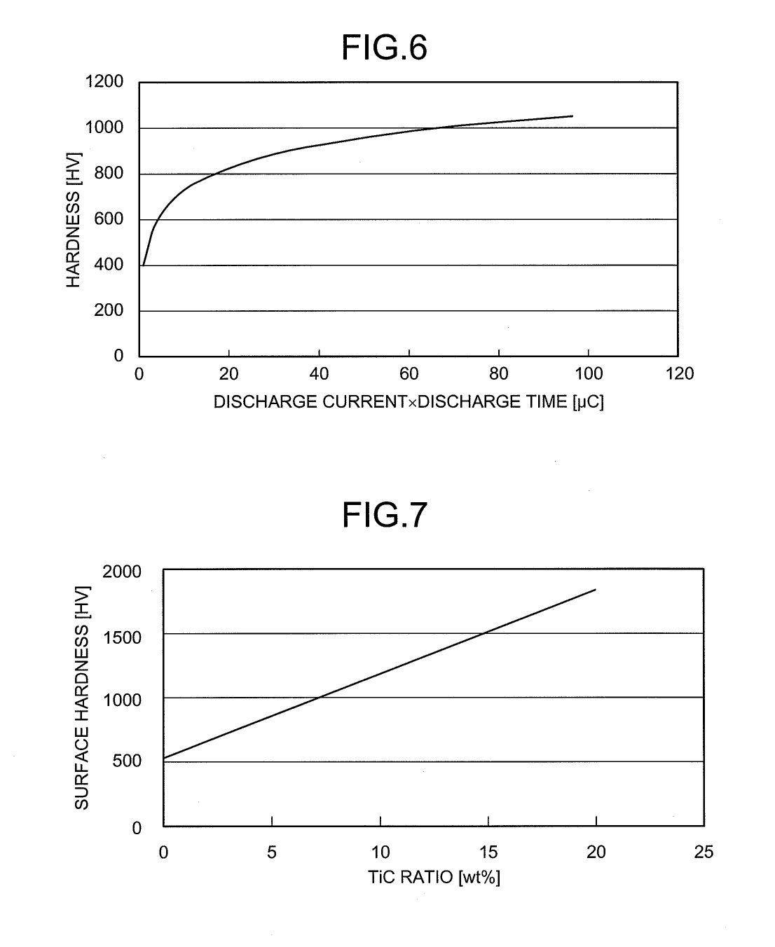

A relation between a product of discharge current and discharge time, and hardness of surface of film upon forming the film on a target workpiece made of S45C having a hardness of around 300 HV by using an electrode with a resistance of 0.02Ω is shown in FIG. 6.

The processing time was set long so that temperature of the surface of the workpiece sufficiently increased due to discharge.

As charge amount increased, the hardness of the surface increased. This is because working fluid was dissolved due to energy of discharge, so that carbon was generated, and the carbon was molten into the surface of the molten workpiece. As a result, amount of carbon increased, resulting in increasing the hardness of the surface.

It is assumed that the amount of molten carbon increases as discharge amount increases, resulting in increasing the hardness.

Carbon is began to be precipitated in advance of other materials because the boiling point of carbon is about 4000K, so that the surface is in a carbon-rich condition when the workpiece begins to be clumped.

Thus, it is possible to adjust the hardness of the surface of the film by controlling discharge current and discharge time.

According to the first embodiment, it is possible to form a Zn, Sn, Ni, or Cr film as a reaction film under lubricant environment containing sulfur or phosphorus, which has been difficult to form by the conventional discharge surface treatment. Thus, it is possible to form a mechanical sliding surface with high abrasion resistance.

Furthermore, the Zn, Sn, Ni, or Cr film has various hardness, and hardly separates from a workpiece.

Moreover, it is possible to control the hardness of the surface of the film by adjusting discharge current and discharge time. Accordingly, it is possible to make the hardness to be the same as that of the counter workpiece to be slid. Therefore, workpieces are hardly abraded, and durability and reliability of the workpieces can be improved.

Furthermore, the surface of the film is less sheared by forming the film so that its hardness is lower than that of the counter workpiece. Thus, it is possible to lower coefficient of friction.

Although an example of the Zn film is described above, substantially the same result was obtained from Sn, Ni, and Cr films. Among them, an example of a Sn film is additionally described below. A sliding test was performed to the Sn film with the lubricant containing S in a range from 0.006 wt % to 0.30 wt % and P in a range from 100 ppm to 600 ppm dropped at 5 cc/min. The counter workpiece was a quenched/tempered steel pin made of SKS-95, of which end portion had curvature radius of 18 millimeters, and hardness was in a range from HRC 60 to HRC 64. The end portion of the pin was pressed to the film with a load of 5 kgf, and slid back and forth for 50 millimeters with a cycle of 200 cpm. As a result, it was found that the reaction film was formed, coefficient of friction increased about 10% compared with a polished surface made of SCM 420, and wear volume decreased compared with unprocessed material.

### Second Embodiment

According to the first embodiment, a method of changing hardness of the surface of the film by discharge condition is described.

According to a second embodiment of the present invention, a method of changing hardness of the surface of the film by changing the hardness of the workpiece is described below.

As described above, the hardness of solid metal of Zn or Ni capable of forming a reaction film is equal to or less than 100 HV, so that if the film made of Zn or Ni with a thickness of 0.1 millimeter or more is deposited, the hardness of the surface of the film has the hardness as the same as or slightly larger than that of the solid metal of Zn or Ni.

However, by setting the thickness of the film equal to or less than 3 micrometers, the hardness of the workpiece becomes closely related to the hardness of the surface of the film, without being affected by composition of the film.

A steel having different hardness of its surface due to carburizing process, nitriding process, high frequency quenching, or electron beam quenching is used as the workpiece, and a Zn, Sn, Ni, or Cr film having thickness equal to or thinner than 3 micrometers is formed on the steel.

The discharge surface treatment was performed by using a Zn electrode having a resistance of 0.074Ω in a size of 60×16×2 in working fluid mainly containing kerosene, in such a manner that pulsed electric discharge was generated with a peak current of 5 A for discharge time of 0.5 microsecond, and interval between discharges of 2 microseconds (the interval may be prolonged during a process due to jump operation or servo control), on a steel made of SCM 420 that had been hardened to about 1000 HV by carburizing process and tempering, for processing time of 0.6 seconds per unit area of 1 square millimeter.

The processing time was set shorter than that described in FIG. 6. It is because, if the processing time is set longer, the temperature of the surface of the workpiece increases due to heat by discharge, so that carburizing process is generated or thickness is widened as described in the first embodiment, resulting in decreasing the hardness of the surface of the film.

If the processing time per unit area is shorter than 0.6 second, a Zn film is not formed sufficiently, resulting in generating uncoated portions on the surface of the workpiece. If the uncoated portions on the surface of the workpiece increase, a ratio of an area where a Zn reaction film is not formed increases. As a result, the effect of the reaction film decreases, e.g., the wear volume increases, compared with the case where the entire surface is coated by the Zn film.

The surface roughness Ra of the film formed under the above condition was 0.2 micrometer, the hardness of the surface of the film at a test force of 10 gf was 940 HV, and Zn amount obtained by the EDS with acceleration voltage of 15 kV was 10.0 wt %.

The thickness of the film was about 2 micrometers, and the hardness of the film was hardly degraded.

A sliding test was performed to the counter workpiece with the lubricant containing S in a range from 0.006 wt % to 0.30 wt % and P in a range from 100 ppm to 600 ppm dropped at 5 cc/min. The counter workpiece was a quenched/tempered steel pin made of SKS-95, of which end portion had curvature radius of 18 millimeters, and hardness was in a range from HRC 60 to HRC 64. The end portion of the pin was pressed to the film with a load of 5 kgf, and slid back and forth for 50 millimeters with a cycle of 200 cpm. As a result, it was found that the reaction film was formed, coefficient of friction increased about 10% compared with a polished surface made of SCM 420, and wear volume decreased compared with unprocessed material.

A discharge surface treatment was performed by using a Zn electrode having a resistance of 0.074Ω in a size of 60×16×2, in such a manner that pulsed electric discharge was generated with a peak current of 7 A for discharge time of 0.5 microsecond, and interval between discharges of 2 microseconds (the interval may be prolonged during a process due to jump operation or servo control), on a steel made of SCM 420 that had been hardened to about 1000 HV by carburizing process and tempering for processing time of 0.6 seconds per unit area.

The surface roughness Ra of the film formed under the above condition was 0.3 micrometer, the hardness of the surface of the film at a test force of 10 gf was 920 HV, and Zn amount obtained by the EDS with acceleration voltage of 15 kV was 12.0 wt %.

A discharge surface treatment was performed by using a Zn electrode having a resistance of 0.074Ω in a size of 60×16×2 in working fluid mainly containing kerosene, in such a manner that pulsed electric discharge was generated with a peak current of 10 A for discharge time of 1 microsecond, and interval between discharges of 2 microseconds (the interval may be prolonged during a process due to jump operation or servo control), on a steel made of SCM 420 that had been hardened to about 1000 HV by carburizing process and tempering for processing time of 0.6 seconds per unit area.

The surface roughness Ra of the film formed under the above condition was 0.8 micrometer, the hardness of the surface of the film at a test force of 10 gf was 900 HV, and Zn amount obtained by the EDS with acceleration voltage of 15 kV was 12.0 wt %.

When peak current was 12 A and discharge time was 2 microseconds, the hardness of the surface of the film decreased to 800 HV even when the processing time was shortened.

Thus, for increasing the hardness of the surface of the film by using the hardness of the workpiece, it is necessary to set peak current to be equal to or smaller than 10 A for discharge time equal to or less than 1 microsecond. If peak current is smaller than 0.1 A, and discharge time is less than 0.1 microsecond, energy is not sufficient for melting particles that have escaped from the workpiece or the electrode. Therefore, it is difficult to form a film by discharge surface treatment. Thus, each of discharge conditions needs to be set larger than the above value.

A Zn film was formed on S45C that had been hardened to about 400 HV under such conditions that peak current was equal to or less than 10 A, discharge time was equal to or less than 1 microsecond, interval between discharges was 2 microseconds (the interval may be prolonged during a process due to jump operation or servo control), and processing time was 0.6 seconds per unit area.

The hardness of the surface of the film at a test force of 10 gf was about 400 HV. Furthermore, the Zn film was formed under the above discharge condition on S45C that had been hardened to about 600 HV. The hardness of the surface of the film at a test force of 10 gf was about 500 HV. Moreover, the Zn film was formed under the above discharge condition on S45C that had been hardened to about 800 HV by water quenching. The hardness of the surface of the film at a test force of 10 gf was about 77 HV.

The hardness of the workpiece decreases from the surface to the inside due to carburizing process, nitriding process, and quenching process. Accordingly, if the film having high hardness is formed until the film has desired hardness by carburizing, nitriding, or quenching, and such a Zn film is then formed on a polished surface by discharge surface treatment, it is possible to form the Zn film with desired hardness.

Although steel is explained in the second embodiment, it is possible to form a Zn film having hardness substantially the same as that of solid metal by forming the Zn film on solid metal of aluminum alloy or molybdenum alloy by discharge surface treatment.

According to the second embodiment, it is possible to form a Zn, Sn, Ni, or Cr film as a reaction film under lubricant environment containing sulfur or phosphorus, which does not separate from a workpiece and has various hardness.

Furthermore, it is possible to form a film with high hardness by using Zn or Ni having low solid-metal hardness by using the hardness of the workpiece.

Therefore, if the abrasion target material and the counter workpiece are made of the same material, it is possible to form a film without degrading the hardness, so that the abrasion target material and the counter workpiece are hardly abraded. As a result, durability and reliability of the abrasion target material and the counter workpiece can be improved.

Moreover, if the hardness of the surface of a process target material is set slightly lower than that of the counter workpiece, the surface of the film can be less sheared, and coefficient of friction can be lowered.

### Third Embodiment

For using property of a reaction film in a boundary lubrication area, e.g., for decreasing coefficient of friction or preventing abrasion, the surface roughness of the film needs to be considered.

If the surface roughness is large, pressure on some portions increases, so that lubrication hardly comes into the portions, resulting in making it difficult to form the reaction film.

According to a third embodiment of the present invention, the surface roughness of the sliding member for forming the reaction film is considered.

A discharge surface treatment was performed by using an electrode having a resistance of 0.074Ω in a size of 60×16×2 in working fluid mainly containing kerosene, with peak current of 8 A for discharge time of 8 microseconds, and interval between discharges of 128 microseconds, on a steel made of SCM 420 that had been quenched, for processing time of 5 seconds per unit area of 1 square millimeter.

The generated surface roughness Ra was 2.0 micrometer. As the surface roughness decreases, the reaction film can be more easily formed, so that it is preferable to set the surface roughness of equal to or less than 1.0 micrometer in consideration of actual usage.

In some cases, the film is formed with discharge current or discharge time that are larger than those described above to increase the thickness of the Zn film or increase the accumulated amount of the Zn film. In this case, the surface roughness increases. A method of removing protruding portion, which is formed by discharge surface treatment and increases the surface roughness, by discharge process is described below.

During a removal process, an electrode made of solid metal that is the same material as that of the film is used, and a surface to be processed is placed in parallel in an opposite position to the film.

If the electrode made of solid metal that is the same material as that of the film is not used, the electrode may be slightly evaporated due to heat by discharge, so that evaporated material may be mixed to the film as impurity.

For example, if processed by using a Cu—W electrode, which is generally used for electrical discharge process, W (tungsten) is attached to the surface of the film.

Specifically, the protruding portion was removed so that the thickness of the film become equal to or thinner than 5 micrometers by discharge process under such processing condition that an electrode made of solid metal of Zn was used with peak current of 8 A for discharge time of 1 microsecond, and interval between discharges of 8 microseconds (the interval may be prolonged during a process due to jump operation or servo control), for a Zn film in a size of 60×16 by using a Zn solid metal electrode having processing area of 16×2, with a predetermined space kept between the electrode and the film by servo, shifting the electrode toward the film by 60 millimeters.

The surface roughness Ra of the Zn film formed in the above manner was 0.4 micrometer, so that a reaction film can be formed in lubricant atmosphere containing phosphorus and sulfur.

If an electrode in the same size (60×16) as that of the film is used for the removal process, it is difficult to arrange the electrode and the film in parallel, facing each other with accuracy of a few micrometers. Therefore, discharge is exclusively generated in a portion where distance between the film and the electrode is short, resulting in causing variation in finishing of the surface.

Although the protruding portion of the film can be removed at the time of the beginning of the process, when the process is continued, the processing surface of the Zn solid metal electrode is removed due to discharge generated upon removing the protruding portion. Therefore, a portion where the Zn film is made thinner and the solid metal electrode come close to each other, so that discharge is generated and the Zn film with appropriate thickness (thin) is removed.

As described in the third embodiment, when an electrode in a size smaller than that of the film, i.e., an electrode in a size of 2×16, is used for the film in a size of 60×16, and process is performed by shifting the electrode by servo control, discharge is generated at the most highest portion (protruding portion) of the film. Therefore, the protruding portion of the Zn film can be exclusively removed, and the surface of the film can be uniformly finished.

The shifting speed of the electrode is sufficient as long as it is equal to or faster than 2 millimeters per minute.

As another method of removing the protruding portion, barrel polishing was applied to the Zn film formed in the above manner by using polishing agent made of Al₂O₃ or SiO₂, with frequency of rotation of 180 rpm for a processing time of 1 hour.

The surface roughness Ra after finishing by the barrel polishing was 0.8 micrometer, which was sufficient for forming the reaction film.

Although Zn is mainly explained in the third embodiment, materials, such as Sn, Ni, and Cr, other than Zn can form the reaction film with phosphorus or sulfur.

A method of forming an electrode using such materials is described above. A film with the surface roughness of equal to or less than 1.0 micrometer can be formed in a method similar to that of Zn, and the surface roughness can be lowered in the above manner.

According to the third embodiment, the surface roughness Ra can be set equal to or less than 1.0 micrometer, and it is possible to form a Zn, Sn, Ni, or Cr film as a reaction film under lubricant environment containing sulfur or phosphorus, which does not separate from the workpiece and has various hardness.

### Fourth Embodiment

A film processing method in which a reaction film can be formed by changing not the discharge condition but material of an electrode, and the hardness of the surface can be set equal to or harder than 200 HV is described according to a fourth embodiment of the present invention.

It is explained in the first embodiment that a film is formed by using an electrode molded from one of Zn, Sn, Ni, Cr powders. According to the fourth embodiment, it is explained that an electrode made of mixture of ceramic powders, such as TiC, Cr₃C₂, WC, with Zn, Ni, Cr powders.

The reason for mixing ceramic powders of TiC, Cr₃C₂, WC is that such an electrode is used for changing the hardness of the film.

A mixture ratio of TiC powders having a particle diameter of 1 micrometer was changed in a range from 2 wt % to 20 wt % to Zn powders having a particle diameter of 2 micrometers. Such powders were sieved by a sieve having mesh size of 300 micrometers, and a plurality of electrodes in a size of 60×16×2 were formed by compaction molding. A film was formed by using an electrode formed in the above manner by pulsed electric discharge with a peak current of 8 A for discharge time of 1 microsecond, and interval between discharges of 2 microseconds (the interval may be prolonged during a process due to jump operation or servo control), for a sufficient processing time. The hardness of such an film is shown in FIG. 7.

The surface roughness Ra of the film in the above condition was about 0.4 micrometer. Material of S45C (with a hardness of about 300 HV), which has not been quenched or nitriding processed, was used.

For example, the hardness of the film by an electrode with TiC of 5 wt % mixed at a test force of 10 gf was 850 HV, which is larger than that of S45C by 550 HV due to TiC with high hardness.

Furthermore, the hardness of the film formed by an electrode containing 10 wt % of TiC at a test force of 10 gf was increased to 1100 HV from the hardness of about 300 HV of S45C.

It is possible to form a film having various hardness by forming such a film that is made of mixture of ceramics such as TiC, which can form a reaction film, with Zn or Ni.

If equal to or more than 20 wt % of TiC is mixed, the amount of TiC present on the surface of the film increases. As a result, a reaction film is hardly formed. Furthermore, the hardness of the surface of the film exceeds 1500 HV, which is harder than that of materials, such as steel, used in general workpiece, so that a portion of the general workpiece made of steel and the like may be abraded.

For example, a sliding test was performed by using a steel pin, as the counter workpiece, made of SKS-95 that was quenched and tempered, had hardness in a range from HRC 60 to HRC 64, and had end portion having curvature radius of 18 millimeters with lubricant containing S in a range from 0.06 wt % to 0.30 wt % and P in a range from 100 ppm to 600 ppm dropped at 5 cc/min. The end portion of the pin was pressed to the film with a load of 5 kgf, and slid back and forth for 50 millimeters with a cycle of 200 cpm. Upon measuring coefficient of friction and wear volume, with a boundary of TiC of 10 wt %, the wear volume of the steel pin largely increased, and the hardness of the film at this time with a test force of 10 gf exceeded 1200 HV.

Furthermore, it is considered that TiC with high hardness abraded the SKS pin due to solid contact between the pin and the film because TiC did not form a reaction film.

If the mixture ratio of TiC is larger than 10 wt %, the amount of TiC contained in the film increases, so that the hardness of the film increases, resulting in failing to form a reaction film due to excess amount of TiC. Moreover, such an film abrades the counter workpiece.

The same result was generated when TiC was mixed to Sn, Ni, or Cr powders other than Zn powders. Furthermore, the same result was generated when ceramic powders of Cr₃C₂ or WC other than TiC were used.

Thus, when property of the reaction film is used in the boundary lubrication area, equal to or less than 10 wt % of the mixture ratio of ceramic powders of TiC, Cr₃C₂, or WC to the Zn, Sn, Ni, or Cr powders is sufficient.

The particle diameters of the Zn powders or TiC powders described above are far smaller than that of discharge crater, so that it is possible to form a film with ceramics uniformly deposited even when the particle diameter of the electrode varies.

Thus, the hardness of the film is not affected by the mixture ratio even when the particle diameter of the electrode varies.

A process for forming an electrode for discharge surface treatment according to the fourth embodiment is described below.

Zn or Sn powders having an average particle diameter of equal to or smaller than 15 micrometers, and Cr or Ni powders having an average particle diameter of equal to or smaller than 4 micrometers are mixed at 90 wt % to ceramic powders, such as TiC, Cr₃C₂, or WC, having an average particle diameter of 1 micrometer at equal to or less than 10 wt % in a cylindrical container. Highly-volatile organic solvent of twice or more amount by volume of that of the powders is added to the cylindrical container, and the cylindrical container is then sealed. The cylindrical container is then rotated for a few hours to a few tens of hours to mix one of Zn, Sn, Cr, and Ni powders with the ceramic powders uniformly.

If mixing time is too short, the ceramic powders may not be mixed with the Zn powders uniformly, so that density of TiC present on the film does not become uniform. Thus, the mixing time needs to be equal to or longer than 10 hours.

When mixing is finished, the cylindrical container is left as it is for a while, so that the mixed powders are deposited at the bottom of the cylindrical container.

Supernatant solution is then decanted to other container so that the deposited powders are not flown up, and the mixed powders containing a little organic solvent is extracted.

The mixed powders are then dried in a vacuum furnace or in a room temperature atmosphere to volatile the organic solvent.

The dried mixed powders are sieved by a sieve having a mesh size in a range from 100 micrometers to 300 micrometers to separate clumped powders into pieces.

The mesh size is determined based on formability of the a press in a subsequent process, and capability of crashing the clumped powders by explosion force due to discharge when the clumped powders drop in a space between the electrode and the workpiece.

The powders that have been sieved are placed in a mold, and pressed by a punch by applying a predetermined pressure, so that the powders are molded into a powder compact.

The Zn, Sn, or Ni powders have thin oxide films, which can be easily broken by applying pressure, so that powders can be metallically bonded to one another. On the other hand, formability of the Cr powders is not sufficient because oxide film of the Cr powders cannot be easily broken. By mixing wax, such as paraffin, with weight ratio in a range from 1% to 10% to the powders, pressure by a press can be delivered more preferably, and formability can be improved.

A compact formed by compression molding can be used as an electrode for discharge surface treatment as long as the compact has a predetermined hardness by compression. If the hardness is not sufficient, the compact needs to be heated to increase its hardness because discharge cannot be generated.

When wax is used, it is necessary to remove the wax from the compact. Therefore, a compact is heated to a temperature higher than a melting point of the wax to remove the wax.

As a result, an electrode for the discharge surface treatment is formed.

When an electrode is formed by using Zn, Sn, or Ni powders, the powders can be metallically bonded with one another by pressure by a press, so that an electrode having sufficient hardness can be formed without heating.

However, when an electrode is formed by using Cr powders, the hardness of the electrode is not sufficient by pressure by a press, so that it is necessary to perform a heating process to heat the electrode to a temperature in a range from 300° C. to 500° C. after pressing.

According to the fourth embodiment, by mixing ceramics to a material, such as Zn, Sn, Ni, or Cr, capable of forming a reaction film with phosphorus or sulfur, it is possible to set the hardness of the surface of the film at a test force of 10 gf to be equal to or harder than 200 HV.

Furthermore, a Zn film could be formed by forming an electrode for discharge surface treatment having a resistance of 0.002Ω or more. By using such an electrode, an Zn film having the surface roughness Ra of equal to or less than 1 micrometer and the hardness of its surface of equal to or larger than 200 HV could be formed. If the film having above properties is used in a lubricant containing phosphorus or sulfur, a reaction film can be formed, so that the counter workpiece is hardly abraded.

### INDUSTRIAL APPLICABILITY

As described above, a film according to the present invention has high abrasion resistance and therefore hardly flakes off. Moreover, the film can function as a phosphide or sulfide reaction film in lubricant containing phosphorus or sulfur while having different surface hardness. Thus, the film is particularly suitable to be applied to a sliding portion in a boundary lubrication area.

1-24. (canceled)

25. An electrode for discharge surface treatment in which pulsed electric discharge is generated between the electrode and a workpiece to form, on a surface of the workpiece, any one of a film of an electrode material and a film of substance that reacts with the electrode material by energy of the pulsed electric discharge, wherein
the electrode is a compact molded from metal powders or a compact obtained by heating the compact molded from metal powders, and
the electrode contains 90 weight percent or more of zinc powders, tin powders, or nickel powders.

26. The electrode according to claim 25, wherein surface resistance of the electrode measured by a four-probe method is in a range from 0.002 ohm to 4 ohms.

27. The electrode according to claim 25 is made of zinc powders or tin powders having an average particle diameter of equal to or less than 15 micrometers.

28. The electrode according to claim 25 is made of nickel powders having an average particle diameter of equal to or less than 4 micrometers.

29. The electrode according to claim 25 is made of a mixture of 10 weight percent or less of ceramic powders and zinc powders, tin powders or nickel powders, the ceramic powders being one selected from a group consisting of titanium carbide powders, chromium carbide powders, and tungsten carbide powders.

30. An electrode for discharge surface treatment in which pulsed electric discharge is generated between the electrode and a workpiece to form, on a surface of the workpiece, any one of a film of an electrode material and a film of substance that reacts with the electrode material by energy of the pulsed electric discharge, wherein
the electrode is a compact molded from zinc powders or tin powders having a particle diameter of equal to or less than 15 micrometers, or a compact generated by heating the compact, and
surface resistance of the electrode measured by a four-probe method is in a range from 0.002 ohm to 4 ohms.

31. An electrode for discharge surface treatment in which pulsed electric discharge is generated between the electrode and a workpiece to form, on a surface of the workpiece, any one of a film of an electrode material and a film of substance that reacts with the electrode material by energy of the pulsed electric discharge, wherein
the electrode contains 90 weight percent or more of chrome powders, and
surface resistance of the electrode measured by a four-probe method is in a range from 0.002 ohm to 4 ohms.

32. The electrode according to claim 31, wherein the electrode is made of a mixture of 90 weight percent or more of chrome powders and 10 weight percent or less of ceramic powders, the ceramic powders being one selected from a group consisting of titanium carbide powders, chromium carbide powders, and tungsten carbide powders.

33. A discharge surface treatment method for forming on a surface of a workpiece any one of a film of an electrode material and a film of substance that reacts with the electrode material, with a compact molded from metal powders or a compact obtained by heating the compact as an electrode, by energy of pulsed electric discharge generated between the electrode and the workpiece, wherein
the electrode contains 90 weight percent or more of zinc powders, tin powders, chrome powders, and nickel powders, the discharge surface treatment method comprising:
generating pulsed electric discharge between the electrode and the workpiece with a peak current in a range from 1 ampere to 10 amperes for a time period in a range from 0.1 microsecond to 1 microsecond.

34. The discharge surface treatment method according to claim 33, wherein the electrode is made of a mixture of 10 weight percent or less of ceramic powders and zinc powders, tin powders, chrome powders or nickel powders, the ceramic powders being one selected from a group consisting of titanium carbide powders, chromium carbide powders, and tungsten carbide powders.

35. The discharge surface treatment method according to claim 33, further comprising discharging the surface of the workpiece with a metal solid electrode made of material of the electrode to remove a protruding portion from the surface formed by discharge surface treatment.

36. The discharge surface treatment method according to claim 33, further comprising applying any one of polish and shot blast to the surface of the workpiece to remove a protruding portion from the surface formed by discharge surface treatment.

37. A discharge surface treatment method for forming on a surface of a workpiece any one of a film of an electrode material and a film of substance that reacts with the electrode material, with a compact molded from metal powders or a compact obtained by heating the compact as an electrode, by energy of pulsed electric discharge generated between the electrode and the workpiece, wherein
the electrode is a zinc electrode made of zinc powders having an average particle diameter of equal to or less than 15 micrometers, and
surface resistance of the zinc electrode measured by a four-probe method is in a range from 0.002 ohm to 4 ohms, the discharge surface treatment method comprising:
generating pulsed electric discharge between the zinc electrode and the workpiece with a peak current in a range from 1 ampere to 10 amperes for a time period in a range from 0.1 microsecond to 1 microsecond to form any one of a zinc film and an tin film on a surface of the workpiece; and
sliding the zinc film or the tin film with a counter workpiece in lubricant containing phosphorus or sulfur, such that the zinc film or the tin film reacts with phosphorus or sulfur in the lubricant, to form any one of a phosphide reaction film and a sulfide reaction film on the surface.

38. A discharge surface treatment method for forming on a surface of a workpiece a film that, when slid with a counter workpiece in lubricant containing phosphorus or sulfur, reacts with phosphorus or sulfur in the lubricant and forms a phosphide reaction film or a sulfide reaction film, the discharge surface treatment method comprising:
generating pulsed electric discharge between the workpiece and an electrode, the electrode being a compact molded from 90 weight percent or more of zinc powders, tin powders or nickel powders, or a compact obtained by heating the compact; and
forming a mixed layer by melting zinc component, tin component, or nickel component of the electrode into material of the workpiece by energy of the pulsed electric discharge.

39. A discharge surface treatment method for forming on a surface of a workpiece a film that, when slid with a counter workpiece in lubricant containing phosphorus or sulfur, reacts with phosphorus or sulfur in the lubricant and forms a phosphide reaction film or a sulfide reaction film, the discharge surface treatment method comprising:
generating pulsed electric discharge between the workpiece and an electrode, the electrode is made of a mixture of 10 weight percent or less of ceramic powders and 90 weight percent or more of chrome metal powders, the ceramic powders being one selected from a group consisting of titanium carbide powders, chromium carbide powders, and tungsten carbide powders; and
forming a mixed layer by melting chrome component of the electrode into material of the workpiece by energy of the pulsed electric discharge.

40. A discharge surface treatment method for forming on a surface of a workpiece any one of a film of an electrode material and a film of substance that reacts with the electrode material, with a compact molded from metal powders or a compact obtained by heating the compact as an electrode, by energy of pulsed electric discharge generated between the electrode and the workpiece, wherein
the electrode contains 90 weight percent or more of zinc powders, tin powders, chrome powders, or nickel powders, the discharge surface treatment method comprising:
generating pulsed electric discharge between the electrode and the workpiece with a peak current in a range from 4 amperes to 12 amperes for a time period in a range from 2 microseconds to 8 microseconds; and
applying any one of polish and shot blast to the surface of the workpiece to remove a protruding portion from the surface formed by discharge surface treatment.

41. A film that is formed by discharge surface treatment in which pulsed electric discharge is generated between an electrode and a workpiece, the electrode being a compact molded from 90 weight percent or more of zinc powders, tin powders, chrome powders or nickel powders, or a compact obtained by heating the compact, the film comprising:
a mixed layer that is formed by melting of zinc component, tin component, or nickel component of the electrode into material of the workpiece by energy of the pulsed electric discharge.

42. The film according to claim 41, wherein surface hardness of the film is equal to or more than 200 Vickers hardness.

43. The film according to claim 41, wherein surface roughness of the film is equal to or less than 1 micrometer.

44. The film according to claim 41, wherein thickness of the mixed layer is equal to or less than 10 micrometers.

45. A film that, when slid with a counter workpiece in lubricant containing phosphorus or sulfur, reacts with phosphorus or sulfur in the lubricant and forms a phosphide reaction film or a sulfide reaction film on a surface of a workpiece, the film comprising:
a mixed layer that is formed by melting of zinc component, tin component, or nickel component of an electrode into material of the workpiece by energy of pulsed electric discharge generated between the electrode and the workpiece, the electrode being a compact molded from 90 weight percent or more of zinc powders, tin powders or nickel powders, or a compact obtained by heating the compact.

46. A film comprising:
a mixed layer in which any one of zinc, tin, chrome, and nickel is molten into material of a workpiece; and
a reaction film that is formed by reaction between any one of zinc, chrome and nickel, and phosphorus or sulfur in lubricant when the film is slid with a counter workpiece in the lubricant.

47. A film that is formed by discharge surface treatment in which pulsed electric discharge is generated between an electrode and a workpiece, the electrode being a compact molded from 90 weight percent or more of chrome powders or a compact obtained by heating the compact, the film comprising:
a mixed layer that is formed by melting of chrome component of the electrode into material of the workpiece by energy of the pulsed electric discharge, wherein
the mixed layer has a surface hardness of equal to or more than 200 Vickers hardness, a surface roughness of equal to or less than 1 micrometer, and a thickness of equal to or less than 10 micrometers.

48. A method of forming a film comprising:
generating pulsed electric discharge between an electrode and a workpiece, the electrode containing 90 weight percent or more of zinc powders, tin powders, chrome powders or nickel powders, or a compact obtained by heating the compact;
melting zinc component, chrome component or nickel component into material of the workpiece by energy of the pulsed electric discharge to form a mixed layer on a surface of the workpiece; and
sliding the workpiece with a counter workpiece in lubricant containing phosphorus or sulfur, such that the zinc component, the chrome component or the nickel component in the mixed layer reacts with phosphorus or sulfur in the lubricant, to form any one of a phosphide reaction film and a sulfide reaction film on the surface.
